(19) United States
(12) Patent Application Publication
(10) Pub. No.: US 2018/0352663 A1
(43) Pub. Date: Dec. 6, 2018

(54) Device-Mounting Channel with Cradle for Cable

(71) Applicants: David R. Hall, Provo, UT (US); Jerome Miles, Spanish Fork, UT (US); Casey Webb, Spanish Fork, UT (US); Joe Fox, Spanish Fork, UT (US); Jedediah Knight, Provo, UT (US)

(72) Inventors: David R. Hall, Provo, UT (US); Jerome Miles, Spanish Fork, UT (US); Casey Webb, Spanish Fork, UT (US); Joe Fox, Spanish Fork, UT (US); Jedediah Knight, Provo, UT (US)

(21) Appl. No.: 15/608,459

(22) Filed: May 30, 2017

(51) Int. Cl. H05K 5/00; H05K 5/03; H05K 5/06

(52) U.S. Cl. CPC H05K 5/0013; H02G 11/02; H05K 5/069; H05K 5/03

(57) ABSTRACT

A cable management system may include a channel, a cradle, and one or more cables girdled by the channel, the cradle, or both. The channel may include one or more sets of opposing openings. The cradle may be disposed within the channel. The cradle may include a brace. The cradle may include a set of at least two detents disposed in at least one of the sets of opposing openings. Each set op opposing openings may coaxial, non-coaxial, or combinations thereof. The cable management system may further include a channel cover detachably connected to the channel by a second set of detents. Each detent of the second set of detents may be disposed in at least one of the opposing openings. Each detent of the second set of detents may be disposed across the corresponding opening from a corresponding one detent of the first set of detents.

### TECHNICAL FIELD

This invention relates generally to the field of the Internet of Things and more specifically to smart home devices.

### BACKGROUND

The proliferation of the Internet of Things (IoT) has led to many advances in smart home devices. Examples include smart window blinds, smart thermostats, smart lighting, and smart garages. In garages, the smart devices may include a variety of tools, including the garage door, lifting devices, lights, speakers, and other electronic devices. However, such advanced technological developments still require solutions to menial problems. One such problem is cable management. Devices not wired directly to mains electricity will need to be powered either by battery, or by plugging in to mains electricity via an outlet. Managing cords and cables has become a unique niche related to electronic technologies. Currently, virtually every cable management system is passive. However, new technologies and arrangements of devices require new ways of managing cords and cables. Thus, there is ongoing room for improvement in cable and cord management.

### SUMMARY OF THE INVENTION

Embodiments of a cable management system are described herein that address at least some of the cable management issues presented by new and emerging IoT systems. In various embodiments, the system may be an active cable management system. The system may include a channel, one or more current-carrying cables, and a cradle. The channel may include a base, two walls extending perpendicularly from opposing ends of the base, and one or more sets of opposing openings. The cables may run along a length of the channel. The cradle may be disposed in the channel, around the channel walls across a gap between the channel walls and opposite the base, or in the channel and around the channel walls. The cradle may include a cradle base, two walls extending perpendicularly from the cradle base, and a set of at least two detents. Each detent may protrude from at least one of the cradle walls, and each detent may be disposed in at least one of the sets of opposing openings. The cradle may include first and second wiring disposed in the cradle base. Each of the first and second wiring may be arranged in a rectangular closed loop such that the first wiring passes along first-side edges of the cradle base and across a center portion of the cradle base parallel to the cradle walls, and such that the second wiring passes along second-side edges of the cradle base and across the center portion of the cradle base parallel to the cradle walls. First and second resistive elements may be connected in series with the first and the second wiring, respectively, and may be disposed in the cradle base. One or more batteries may be connected to the first and second wiring. A switch may be connected between the battery and the first and second wiring. A current may pass through the first and second wiring along the center portion of the cradle base in a same direction as a current passing through the cables, attracting the cables towards the center portion of the cradle.

In various embodiments, a cable management system may include a channel, a cradle, and one or more cables girdled by the channel, the cradle, or both. The channel may include one or more sets of opposing openings. The cradle may be disposed within the channel. The cradle may include a brace. The cradle may include a set of at least two detents disposed in at least one of the sets of opposing openings. Each set op opposing openings may coaxial, non-coaxial, or combinations thereof. The cable management system may further include a channel cover detachably connected to the channel by a second set of detents. Each detent of the second set of detents may be disposed in at least one of the opposing openings. Each detent of the second set of detents may be disposed across the corresponding opening from a corresponding one detent of the first set of detents.

The cradle may form a shape complementary to the channel. Each of the channel and the cradle may include a base and at least two opposing walls extending from the base. The cradle base may form the brace. The opposing openings may be disposed in the channel walls. The first set of detents may protrude from outer surfaces of the cradle walls. The cradle walls may press against inner surfaces of the channel walls, securing the detents in the openings.

The cradle may include a first, a second, a third, and a fourth cradle wall. The channel may include a first and a second channel wall. The first channel wall may be disposed between the first and second cradle walls. The second channel wall may be disposed between the third and fourth cradle walls. The first set of detents may protrude from an inner surface of the first cradle wall, from an outer surface of the second cradle wall, from an outer surface of the third cradle wall, from an inner surface of the fourth cradle wall, or combinations thereof. The detents protruding from the first and second cradle walls may be disposed in the same opening or different openings. The detents protruding from the third and fourth cradle walls may be disposed in the same opening or different openings.

The channel may be disposed above the cradle such that the weight of the cable is against the brace. The system may include one or more grasping levers connected to, and extending from, the cradle.

The channel may include at least two sets of coaxial openings. The brace may be disposed between the two sets of coaxial openings. The detents may be disposed on members, such as arms, extending from the brace towards at least one of the sets of coaxial opposing openings.

In various embodiments, the cradle may include one or more horseshoe clips extending from the brace.

### BRIEF DESCRIPTION OF THE DRAWINGS

A more particular description of the system summarized above is made below generally and by reference to specific embodiments. Several embodiments are depicted in drawings included with this application, in which:

FIGS. 1A-D depict an overhead mounting system in which the cradle described herein may be useful;

FIGS. 2A-B depict various views of some overhead mounting system components;

FIGS. 3A-B depict various views of an embodiment of a hybrid cover-cradle;

FIG. 4 depicts a cradle incorporating various cable clips;

FIGS. 5A-B depict two views of a cradle according to one embodiment;

FIGS. 6A-B depict two embodiments of an active cradle;

FIG. 7 depicts a system view of an active cradle;

FIG. 8 depicts a more generalized system diagram of the active cradle; and

FIG. 9 depicts a partial schematic of an active cradle circuit.

### DETAILED DESCRIPTION

A detailed description of embodiments of a cable management system is provided below by example, with reference to embodiments in the appended figures. Those of skill in the art will recognize that the features of the system as described by example in the figures below could be arranged and designed in a variety of different configurations without departing from the scope of the claims. Thus, the detailed description below and the depictions of embodiments in the figures is representative of the claimed invention, and is not intended to limit the scope of the claims.

In various embodiments, the system may be an active cable management system. The system may include a channel, one or more current-carrying cables, and a cradle. The channel may include a base, two walls extending perpendicularly from opposing ends of the base, and one or more sets of opposing openings. The cables may run along a length of the channel. The cradle may be disposed in the channel, around the channel walls across a gap between the channel walls and opposite the base, or in the channel and around the channel walls. The cradle may include a cradle base, two walls extending perpendicularly from the cradle base, and a set of at least two detents. Each detent may protrude from at least one of the cradle walls, and each detent may be disposed in at least one of the sets of opposing openings. The cradle may include first and second wiring disposed in the cradle base. Each of the first and second wiring may be arranged in a rectangular closed loop such that the first wiring passes along first-side edges of the cradle base and across a center portion of the cradle base parallel to the cradle walls, and such that the second wiring passes along second-side edges of the cradle base and across the center portion of the cradle base parallel to the cradle walls. First and second resistive elements may be connected in series with the first and the second wiring, respectively, and may be disposed in the cradle base. One or more batteries may be connected to the first and second wiring. A switch may be connected between the battery and the first and second wiring. A current may pass through the first and second wiring along the center portion of the cradle base in a same direction as a current passing through the cables, attracting the cables towards the center portion of the cradle.

In various embodiments, the cable management system may include a channel, a cradle, and one or more cables girdled by the channel, the cradle, or both. The channel may include one or more sets of opposing openings. The cradle may be disposed within the channel. The cradle may include a brace. The cradle may include a set of at least two detents disposed in at least one of the sets of opposing openings. Each set op opposing openings may coaxial, non-coaxial, or combinations thereof. The cable management system may further include a channel cover detachably connected to the channel by a second set of detents. Each detent of the second set of detents may be disposed in at least one of the opposing openings. Each detent of the second set of detents may be disposed across the corresponding opening from a corresponding one detent of the first set of detents.

The cradle may form a shape complementary to the channel. Each of the channel and the cradle may include a base and at least two opposing walls extending from the base. The cradle base may form the brace. The opposing openings may be disposed in the channel walls. The first set of detents may protrude from outer surfaces of the cradle walls. The cradle walls may press against inner surfaces of the channel walls, securing the detents in the openings.

The cradle may include a first, a second, a third, and a fourth cradle wall. The channel may include a first and a second channel wall. The first channel wall may be disposed between the first and second cradle walls. The second channel wall may be disposed between the third and fourth cradle walls. The first set of detents may protrude from an inner surface of the first cradle wall, from an outer surface of the second cradle wall, from an outer surface of the third cradle wall, from an inner surface of the fourth cradle wall, or combinations thereof. The detents protruding from the first and second cradle walls may be disposed in the same opening or different openings. The detents protruding from the third and fourth cradle walls may be disposed in the same opening or different openings.

The channel may be disposed above the cradle such that the weight of the cable is against the brace. The system may include one or more grasping levers connected to, and extending from, the cradle.

The channel may include at least two sets of coaxial openings. The brace may be disposed between the two sets of coaxial openings. The detents may be disposed on members, such as arms, extending from the brace towards at least one of the sets of coaxial opposing openings.

In various embodiments, the cradle may include one or more horseshoe clips extending from the brace.

The channel and the covers may be similar to that described in U.S. patent application Ser. No. 15/487,999 by David Hall et al. for “Overhead Mounting System” and U.S. patent application Ser. No. 15/488,860 by David Hall et al. for “Overhead Mounting System for Daisy-Chained Devices.” Various portions of those applications are reproduced below, and the entirety of each application is incorporated herein by reference.

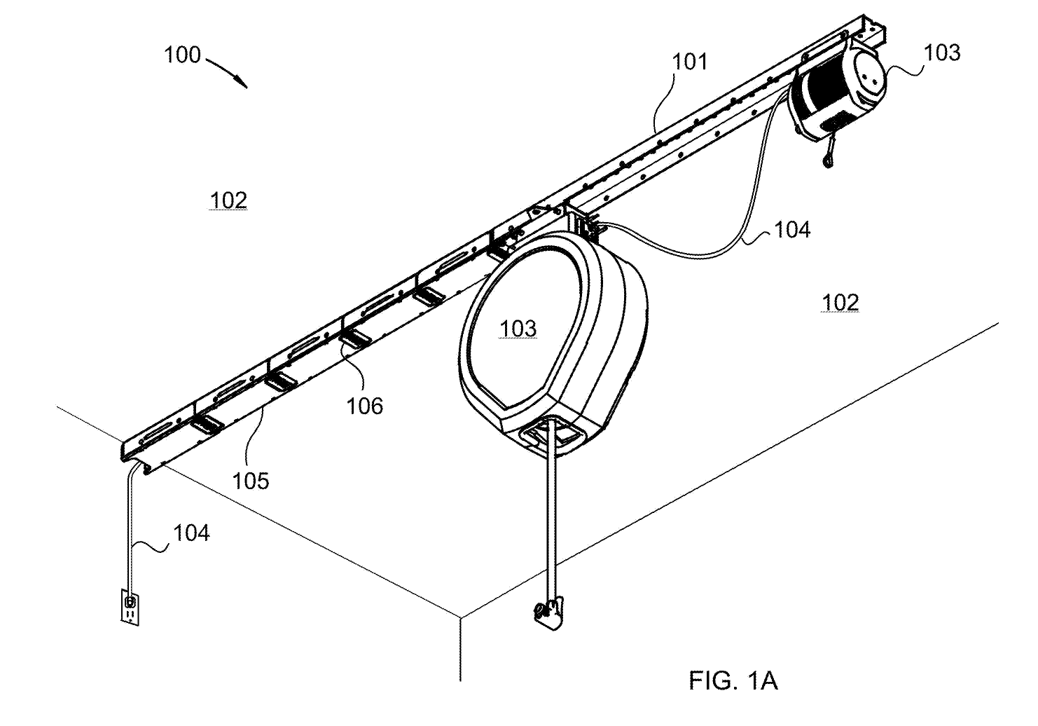

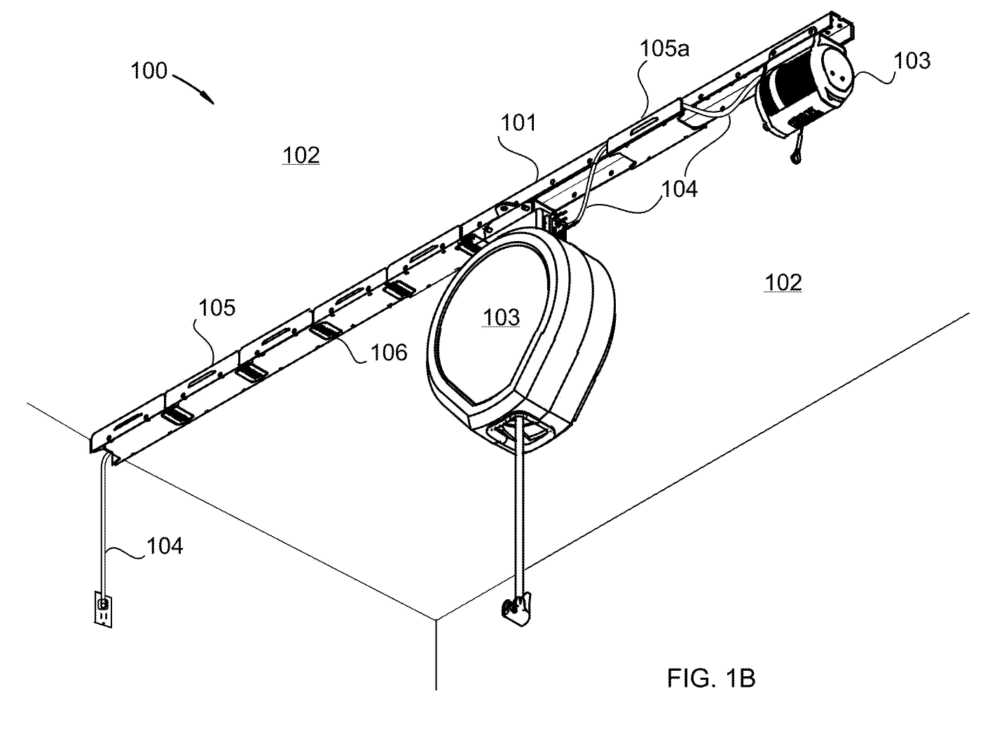

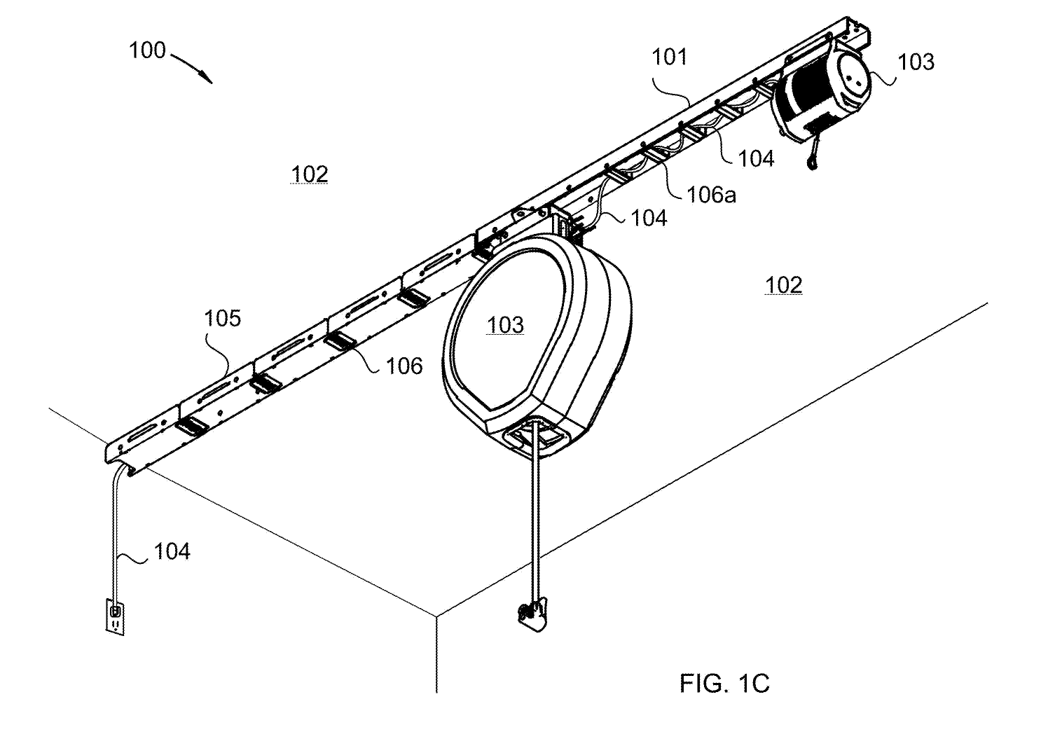

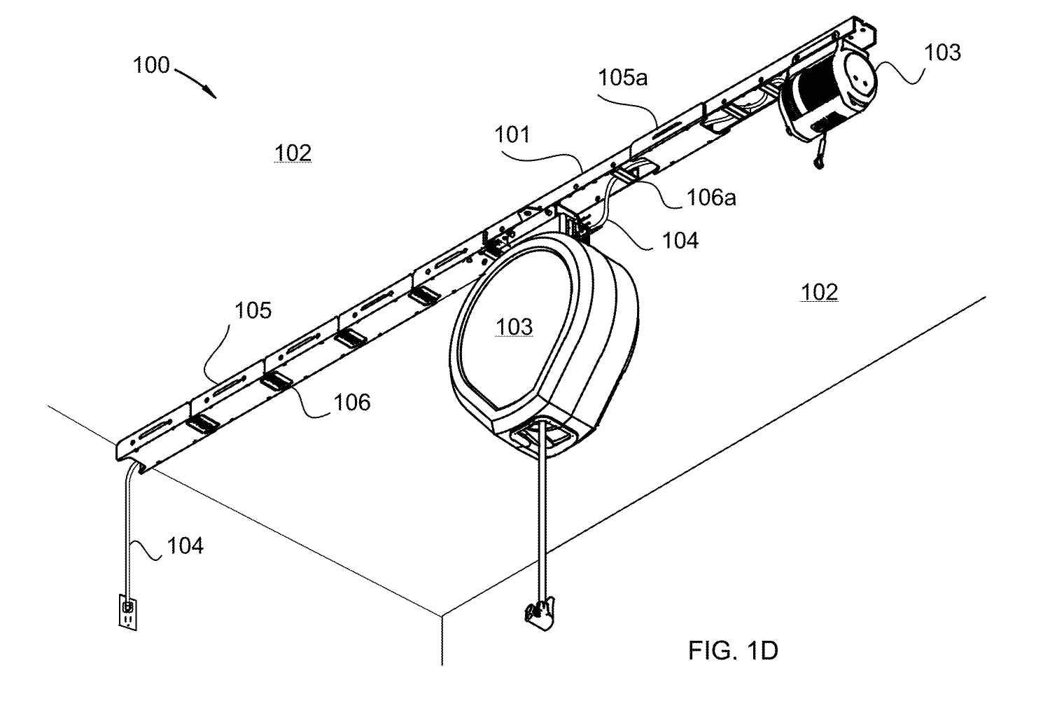

FIGS. 1A-D depict an overhead mounting system in which the cradle described herein may be useful. The system 100 includes, generally, a channel 101 mounted to an overhead surface 102, various devices 103 connected to the channel 101, a cable 104 that provides power to the devices 103 and daisy-chains the devices 103, channel covers 105, and cradles 106. Generally, one or more electronic devices may be mounted to the channel 101. The devices may include cabling 104, such as data wiring and/or power cords, herein generically referred to as cables. The cables 104 may extend along the channel between devices, to routers, and/or to power outlets. Covers 105 may be used to hide the cables 104 within the channel 101 and allow flexibility in positioning of devices. Such covers 105 may wrap at least partially around the channel 101. A user installing a cover 105 may encounter difficulty with the cables 104 becoming snagged on the cover 105 and/or getting trapped outside the channel 101 between the channel 101 and the cover 105. When the channel 101 and devices are mounted overhead, this can be particularly problematic, and may even become dangerous for a user installing the channel 101 and devices.

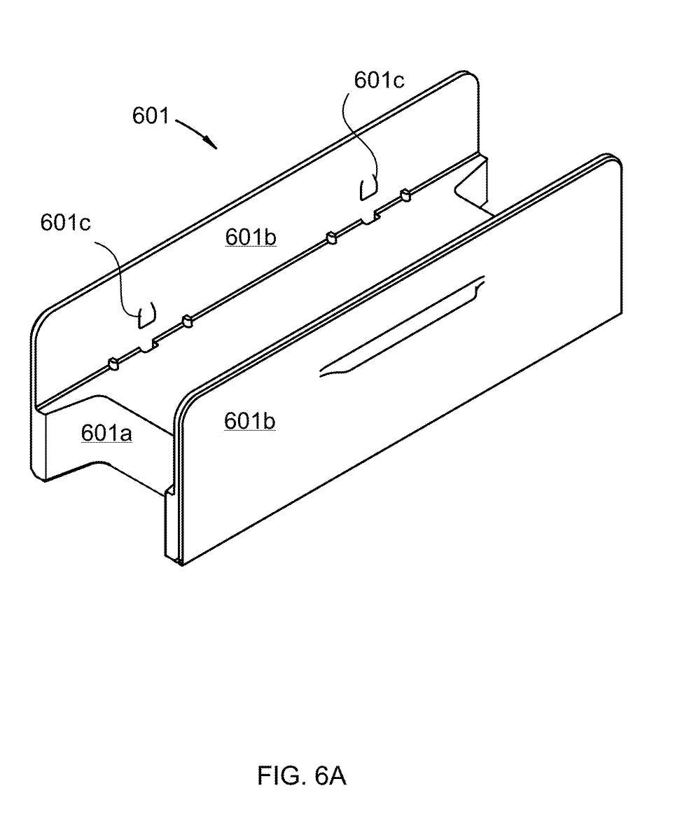

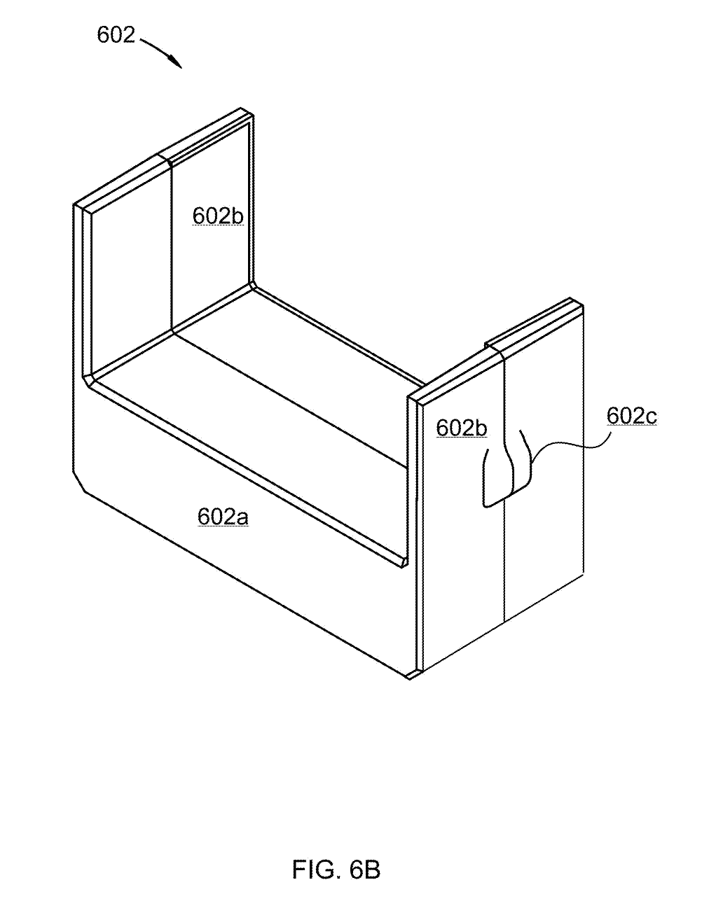

The cradle 106 may provide a simple, active and/or passive solution to cables 104 that spill out of the channel 101 and/or covers 105. In various passive embodiments, because at least a portion of the cradle 106 fits in the channel 101, a cable 104 within the cradle 106 will necessarily be confined within the channel 101. Once the cable 104 is confined within the channel 101, the covers 105 may be simply installed without snagging the cable 104 or trapping it outside the channel 101. In various active embodiments (described below in more detail regarding at least FIGS. 6A-9), the cable may be attracted to a center portion of the cradle, away from walls of the channel as the cradle is mounted to the channel.

As shown in FIG. 1A, on the left side of the devices 103, the cradles 106 hold the cable 104 within the channel 101 such that the covers 105 may be easily mounted to the channel 101 without entangling the cable 104. Between the devices 103, however, the cable 104 hangs freely, unsupported. As shown in FIG. 1B, a cover 105a is mounted to the channel 101 between the devices 103 without first installing a cradle 106. Because the covers 105 wrap around the channel 101, there is nothing to retain the cable 104 within the channel 101. As shown in FIG. 1C, additional cradles 106a are installed in the channel 101. The additional cradles 106a are of a different embodiment than the first cradles 106. The cradles 106a support the cable 104 and girdle the cable 104 within the channel. As shown in FIG. 1D, the cover 105a is easily installed, and the cradle 106 prevents the cable 104 from entangling with the cover 105a.

The channel 101 may be connected to the overhead surface 102. Accordingly, gravity may pull the cable 104 away from the channel 101. The channel 101 may be disposed above the cradle 106 such that the cable 104 is against a cradle brace (described more below). One or more grasping levers may be connected to, and extending from, the cradle 106. The levers may extend an opposite direction from the channel 101. The levers may be connected to the brace, such as by extending from the brace and/or extending from one or more edges of the brace.

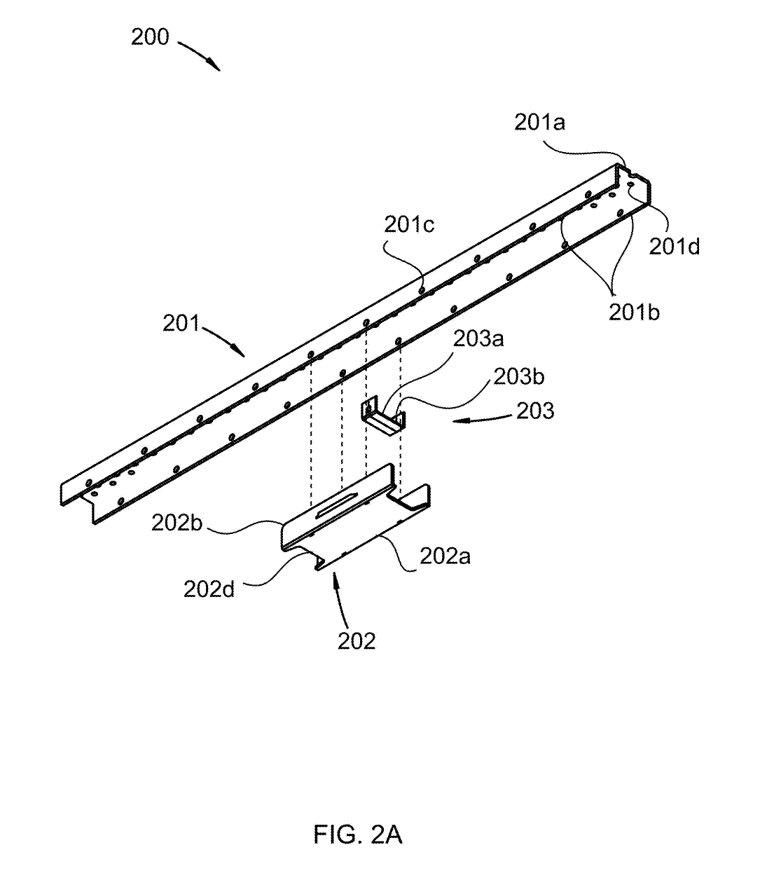

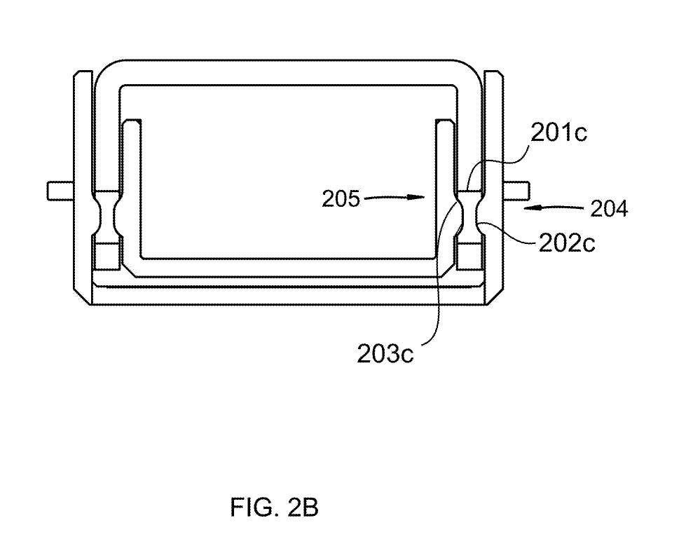

FIGS. 2A-B depict various views of some overhead mounting system components. The system 200 includes a channel 201, a cover 202, and a cradle 203. The channel 201 includes a base 201a, two walls 201b, and openings 201c. The cover similarly includes a base 202a, two walls 202b, detents 202c, and concavities 202d at the ends of the cover 202. The cradle 203 includes a brace 203a, two walls 203b, and detents 203c. The cradle, cover, and channel have complementary forms. As shown in FIG. 2B, the cover detents 202c and cradle detents 203c share the openings 201c. On each of the left and right side, the cover detents 202c occupy an outer side 204 of the openings 201c, and the cradle detents 203c occupy an inner side 205 of the openings 201c.

The channel 201 may be used to mount one or more devices to a surface. The surface may include a wall, a floor, or an overhead surface such as a ceiling. The channel 201 may accommodate wiring for the devices. The devices may be daisy-chained by wiring running along the channel. The covers 202 may support and/or hide the wiring. The channel 201, the cover 202, and/or the cradle 203 may be comprised of one or more materials. Such materials may include any of a variety of thermoplastics, including acrylic, ABS, nylon, PLA, polybenzimidazole, polycarbonate, polyether sulfone, polyetherether ketone, polyetherimide, polyethylene, polyphenylene oxide, polyphenylene sulfide, polypropylene, polystyrene, PVC, and/or Teflon, one or more metals, including aluminum, iron, steel, brass, and/or chrome, and/or one or more composite materials including carbon, carbon fiber, and/or fiberglass. Such materials may include combinations of the previously listed materials. In some embodiments, the channel 201 is comprised of powder-coated steel, and the cover 202 and cradle 203 are comprised of injection-molded ABS.

In some embodiments, the channel 201 may be mounted overhead to one or more trusses, such as in a garage. The channel 201 may be mounted directly to the trusses, or may be mounted to the trusses through a ceiling such as a drywall ceiling. The channel 201 may be mounted to the ceiling by two lag bolts screwed into two truss beams. The lag bolts may pass through openings in the channel base 201a. The channel base may comprise external cleats with barbs for hands-free attachment to the mounting surface. The channel 201 may be mounted along a length of a single truss, perpendicular to a single truss, or perpendicular across two or more trusses. A significant problem in designing overhead mounting systems is the variability in inter-truss spacing. Depending on the type of construction and the builder, inter-truss spacing ranges, on average, from 16 inches to 24 inches. Thus, to capture at least a minimum of two trusses at the minimum average inter-truss spacing, the channel 201 must have a length of at least 16 inches. Accordingly, the length of the channel 201 may range from 16 inches to 48 inches in various embodiments. Another factor to consider when designing overhead mounting systems is the average number of devices a consumer will use and what inter-device spacing the average consumer will use.

The channel base 201a may include a flat bar having a narrow width relative to its length. The length-to-width ratio may range from 6:1 to 48:1. The channel walls 201b may extend from sides of the channel base 201a along the length of the channel base 201a. Each channel wall 201b may form an angle with the channel base 201a ranging from 45 degrees to 135 degrees, from 50 degrees to 130 degrees, from 60 degrees to 120 degrees, from 70 degrees to 110 degrees, from 80 degrees to 100 degrees, from 85 degrees to 95 degrees, from 89 degrees to 91 degrees, and/or 90 degrees. In some embodiments, the angle that each channel wall 201b forms with the channel base 201a may vary along the length of the channel 201. In some embodiments, the channel walls 201b may extend from opposite sides of the channel base 201a. The channel walls 201b may similarly include flat bars having narrow widths relative to their lengths. The channel wall 201b length-to-width ratio may range from 6:1 to 48:1. The channel ends may be formed of the end-edges of the channel base 201a and the channel walls 201b and may run along the widths of the channel base 201a and the channel walls 201b.

In some embodiments, the channel base 201a and/or the channel walls 201b may be contoured. The contouring may be along edges of the channel base 201a and/or channel walls 201b, and/or may be along surfaces of the channel base 201a and/or channel walls 201b. The contouring may correspond to contouring in a surface to which the channel 201 may be mounted, or a surface against which the channel 201 may rest. In various embodiments, the contouring in the surface and/or the channel 201 may be non-linear.

The channel base may comprise external cleats with barbs for hands-free attachment to the mounting surface. The channel base 201a may include one or more openings 201d through which the channel base may be mounted to a surface. For example, one or more lag bolts, screws, and/or drywall fasteners may pass through the channel base openings 201d. The channel base openings 201d may have a larger diameter than the channel wall openings 201c. The channel base openings 201d may have a diameter ranging from half an inch to 1½ inches, from ¾ an inch to 1¼ inches, or may be one inch. The channel wall openings 201c may have a diameter ranging from ⅛ an inch to ½ an inch. The channel base openings 201d may be spaced from each other by a channel base inter-opening length. The channel base inter-opening length may range from half an inch to three inches, from one inch to 2½ inches, or from 1½ inches to two inches. The channel base inter-opening length may be shorter than the channel wall inter-opening length. The configuration of the channel openings 201d may simplify installation by allowing a user to easily distinguish the channel base 201a from the channel walls 201b. Additionally, a closer channel base inter-opening spacing may more readily accommodate a variety of inter-truss spacings. The instant inventors have discovered that a ratio of three channel base openings for every two channel wall openings is optimal to balance the variability in inter-truss spacing and the variability in how consumers will typically use the channel 201. Accordingly, the channel 201 may include three channel base openings 201d for every two channel wall openings 201c.

The covers 202 may include a cover base 202a and at least two cover walls 202b. The cover walls 202b may be connected perpendicularly to the cover base 202a such that the cover 202 is u-shaped. The cover walls 202b may each include one or more inward protrusions 202c. At least one of the one or more inward protrusions 202c may be spaced from at least one of the cover ends by half the channel wall opening length. The cover ends may be concaved 202d along the cover base 202a such that a cover base length is less than a cover wall length. In other embodiments, the cover ends may be concaved along one or more of the cover walls such that the cover wall length is less than the cover base length.

The cover 202 may be detachably connected to the channel by a set of protrusions, such as detents 202c. Each detent 202c may be disposed in at least one of the opposing openings 201c in the channel 201. Each of the detents 202c may be disposed across the corresponding opening 201c from a corresponding one of the detents 203c protruding from the cradle 203. In this manner, the cover 202 and the channel 201 may encircle the cradle 203. The cradle 203 may hold the cable within the channel 201 as the cover 202 is placed on the channel 201. This may prevent the cable from getting snagged by the cover 202 or otherwise trapped outside the channel 201 between the cover 202 and the channel 201.

The detents 202c, 203c may facilitate mounting of the cover 202 and the cradle 203, respectively, to the channel 201. Accordingly, the one or more detents 202c, 203c may include a bump having at least one sharp edge and at least one sloped edge, at least two sharp edges and at least two sloped edges, or may be semi-spherical. The sloped edge may be oriented closest to the cover base, or the sloped edges may be oriented perpendicular to the cover ends. The sloped-edge, sharp-edge configurations may allow for ease in placing the cover on, and removing the cover from the channel, and may save in large-scale manufacturing costs by reducing the amount of material required to form the bumps.

The cradle 203 may form a shape complementary to the channel 201. For example, the channel 201 may be u-shaped, and the cradle 203 may be u-shaped. The channel 201 may be v-shaped, and the cradle 203 may have walls extending from the brace 203a to be parallel to the channel walls 201b. In general, the shape of the channel 201 and cradle 203 may be such that a cavity is formed between the brace 203a and the channel 201 that accommodates the cables.

The opposing openings 201c in the channel may be coaxial, non-coaxial, or some sets may be coaxial and some sets may be non-coaxial. The openings 201c may be used to mount various devices to the channel 201 in addition to mounting the cradle 203 within the channel 201 and the cover 202 around the channel 201. The same opening 201c may accommodate the cradle detent 203c and, at an opposite side, the channel detent 202c.

The brace 203a may contain the cables within the channel 201 between the channel 201 and the cradle 203. The brace 203a may be formed by a base wall of the cradle 203. The brace 203a may loosely hold the cables such that the friction between the cables and the brace 203a is negligible compared with the weight of the cables.

The cradle 203 may be secured within the channel 201 by one or more detents 203c on outer surfaces of the cradle 203. The detents 203c may protrude from the outer surfaces. Such outer surfaces may include walls 203b extending from the brace 203a. A width from one wall 203b outer surface to the other wall 203b outer surface may be equal to an inner width of the channel 201. The walls 203b may be angled slightly outwards, such as by between half a degree and two degrees, so that the walls 203b press against inner surfaces of the channel walls 201b. This may secure the detents 203c in the openings 201c in the channel wall.

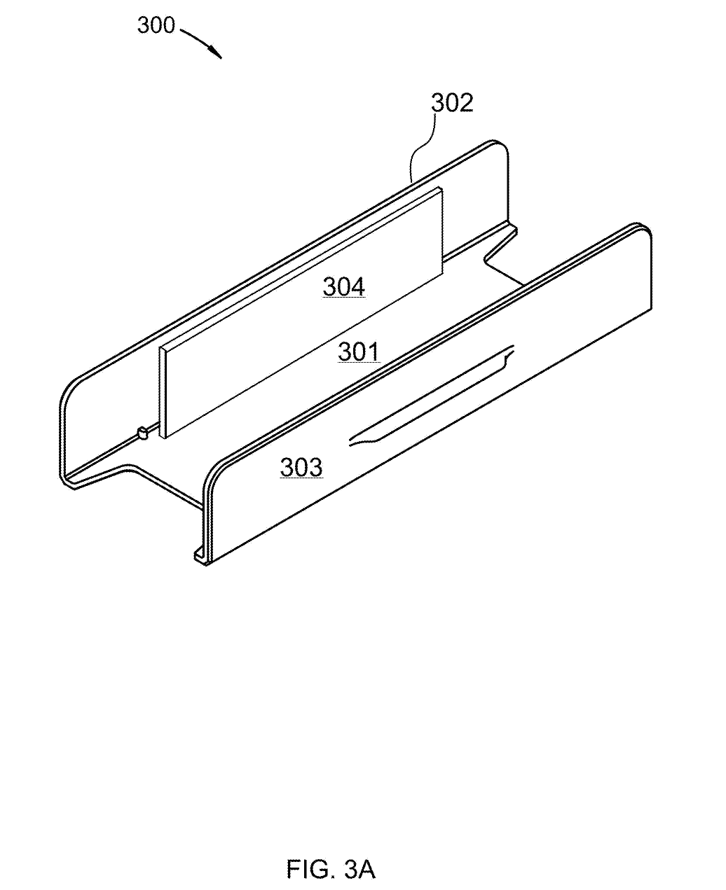

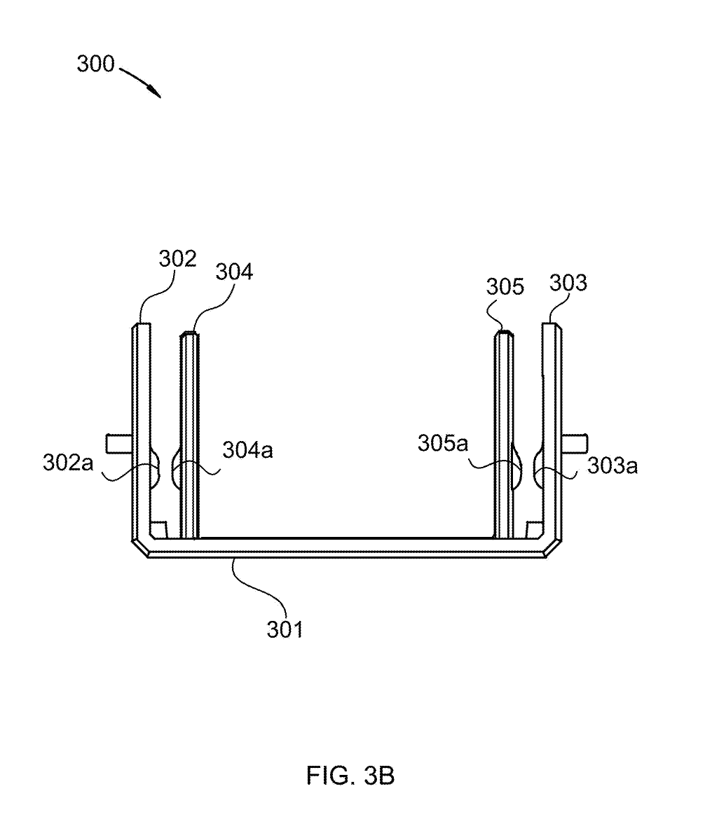

FIGS. 3A-B depict various views of an embodiment of a hybrid cover-cradle. The hybrid cover-cradle 300 includes a base 301, a first outside wall 302, a second outside wall 303, a first inside wall 304, and a second inside wall 305. The first and second outside walls 302, 303 include detents 302a, 303a, respectively. The first and second inside walls 304, 305 include detents 304a, 305a.

As described above, the cradle 300 may include four walls, and the channel may include two walls, each channel wall between two cradle walls. Similar to that described immediately above, the outside walls 302, 303 may be angled slightly inwards, and the inside walls 304, 305 may be angled slightly outwards. A width between the walls 302, 304 and 303, 305, may be, accordingly, slightly less than a thickness of the first and second channel walls, except at the base 301. This may secure the cradle 300 to the channel by friction. Detents 302a, 303a protruding from an inner surface of the outside walls 302, 303 may be positioned in openings in the channel wall. Detents 304a, 305a protruding from an outer surface of the inside walls 304, 405 may similarly be disposed in openings in the channel walls. The detents 302a, 304a or 303a, 305a may be coaxial, and may be disposed in the same opening. For example, the detents 302a, 304a protruding from the outside wall 302 and the inside wall 304 may be disposed in the same opening. Similarly, the detents 303a, 305a protruding from the outside wall 303 and the inside wall 305 may be disposed in the same openings. The channel may include two openings on each side corresponding to the cradle 300, and the detents 302a, 304a and 303a, 305a may be non-coaxial, such that each detent 302a, 303a, 304a, 305a is disposed in a different opening. The detents 302a, 303a may be coaxial, and the detents 304a, 305a may be coaxial.

FIG. 4 depicts a cradle incorporating various cable clips. The cradle 400 includes a base 401, two walls 402, detents 403 disposed on the outer surfaces of the walls 402, a narrow horseshoe clip 404, and a wide horseshoe clip 405. The clips 404, 405 are connected to the base 401. As shown, the clips 404, 405 are integrated with the base 401 such that the cradle 400 is monolithic. The cradle 400 may firmly hold the cables such that the friction between the cables and the cradle 400 is appreciable. For example, the base 401 (or brace, as the case may be) may firmly hold the cables by one or more clips 404, 405. Such clips may, for example, include horseshoe clips, as depicted.

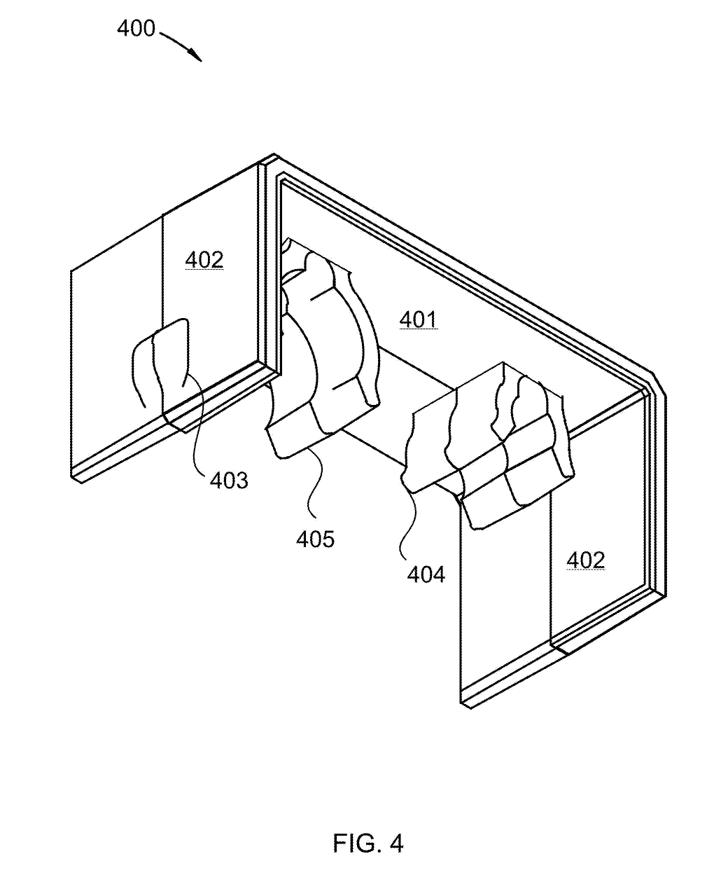

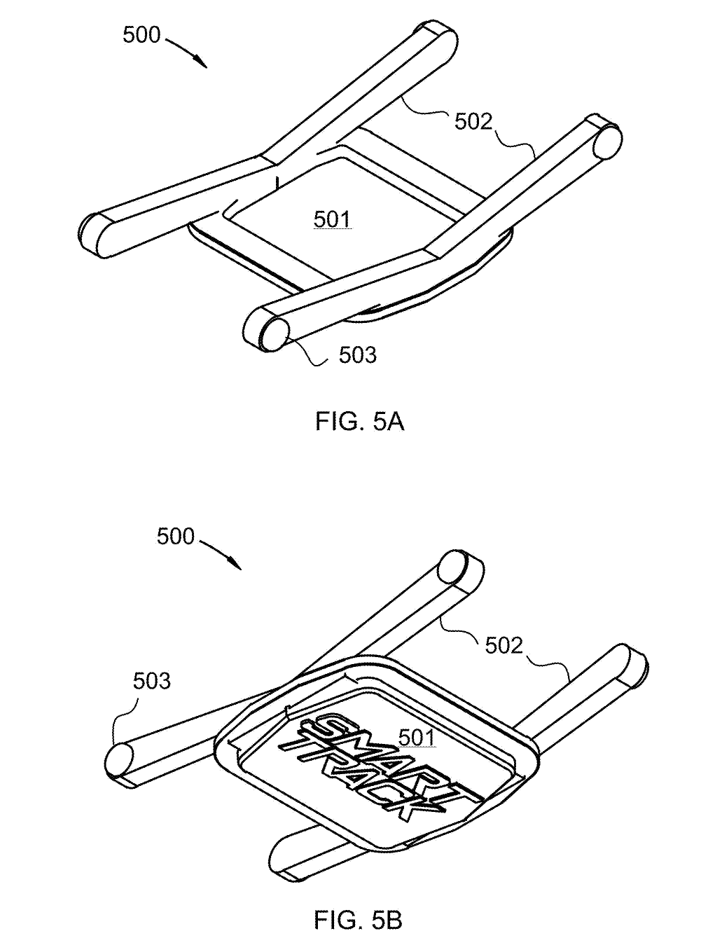

FIGS. 5A-B depict two views of a cradle according to one embodiment. The cradle 500 includes a brace 501, arms 502 extending from the brace 501, and detents 503 at the ends of the arms 502.

The channel may include at least two sets of coaxial openings. The sets may be disposed distally along the length of the channel. The brace 501 may be disposed between the two sets of coaxial openings. The detents 503 may be disposed on members, such as arms 502, extending from the brace 501 towards at least one of the sets of coaxial openings. The brace 501 may, for example, be disposed between two covers in the concavities of the covers. The arms 502 may extend to the openings in which the cover detents are disposed. The cradle detents 503 may be disposed in the same openings as the cover detents.

FIGS. 6A-B depict two embodiments of an active cradle. FIG. 6A depicts a cradle 601 that wraps around the channel walls across a gap between the channel walls and along ends of the channel walls opposite the channel base. The cradle 601 includes a base 601a, two walls 601b extending from the base 601a, and detents 601c extending from the inner surfaces of the walls 601b. FIG. 6B depicts a cradle 602 that fits within the channel. The cradle 602 includes a base 602a, two walls 602b extending from the base 602a, and detents 602c extending from the outer surfaces of the walls 602b. The bases 601a, 602a house the active wiring, power and control electronics that magnetically align the cable.

The active cradle design may allow for more flexibility in design. Accordingly, the cradle may be disposed within the channel, such as cradle 602, with detents 602c disposed on outer surfaces of the cradle walls 602b, or around the channel walls, such as cradle 601 and across a gap between the channel walls opposite the channel base. The detents 601c may be disposed on inner surface of the cradle walls 601b in such an embodiment.

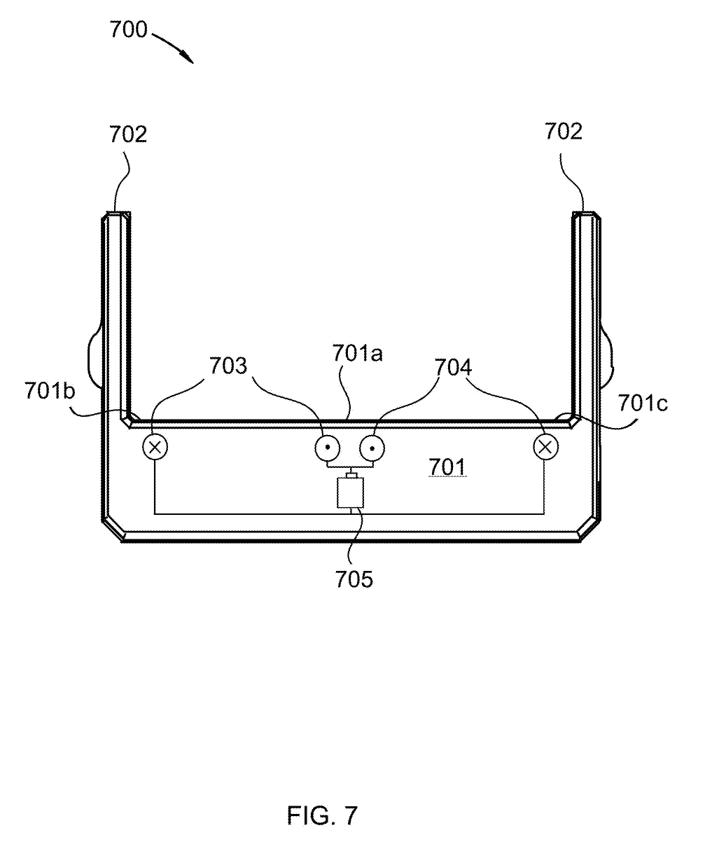

FIG. 7 depicts a system view of an active cradle. The cradle 700 includes a base 701, walls 702, left-side wiring 703, right-side wiring 704, and a battery 705. The base 701 includes a center portion 701a, a left-side edge 701b, and a right-side edge 701c. The battery is connected to the wiring such that current flows in the clockwise direction in the left-side wiring 703, and in the counter-clockwise direction in the right-side wiring 704.

The cradle 700 may provide an active solution to managing cables that spill out of the channel. The left-side wiring 703 (first set of wiring) and a right-side wiring 704 (second set of wiring), each forming a loop in the cradle base 701. The loops may be disposed on opposite sides of the cradle base and may run current in opposite directions. For example, current may flow in a clockwise direction in the left-side wiring 703, and current may flow in a counter-clockwise direction in the right-side wiring 704. Accordingly, along the center portion 701a, the current may flow in the same direction in each loop. The cradle 700 may be aligned with the cable such that the current along the center portion 701a flows in the same direction as the current in the cable. The resulting magnetic fields of the cable and the wiring 703, 704 in the cradle may create an attractive magnetic force between the cable and the center portion 701a, and a repelling force between the cable and the wall-ends of the cradle base 701, including the left-side edge 701b and right-side edge 701c. This attraction may prevent the cable from getting caught between the cradle walls 702 and the channel walls. In some embodiments, the cradle 700 may include a marking feature, such as an arrow, that points the direction the current flows along the center portion 701a.

The wiring 703, 704 powered by battery 705. Power may be delivered to the wiring manually 703, 704 via a manual switch, or automatically via a controller or microcontroller that operates a switch, such as a transistor. The controller may be switched on manually, or may include a magnetic field detector that detects a magnetic field and switches the controller on when a magnetic field is detected. For example, the magnetic field detector may include an inductor that generates a current in the presence of a changing magnetic field. The inductor may be connected to a base terminal of a transistor, the transistor connected between the battery and the controller. The transistor may operate as an amplifier, where a minimal base voltage by the inductor is amplified by the voltage of the battery. Two transistors may be included, one that switches the control and wiring circuit on when the magnetic field detector detects a current in a first direction, and one that switches the control and wiring circuit on, with current flowing the opposite direction in the wiring loops, when the magnetic field detector detects a current in a second direction.

Various embodiments of the active cradle 700 are operable for DC cables that only carry current in one direction. Multiple such cables may be disposed in the channel. The cables will be attracted to portions of the active cradle 700 according to the direction of the current in the cable. Thus, one cable may be disposed along the center portion of the cradle base 701, and one cable may be attracted to one or the other edges 701b, 701c. Various embodiments of the active cradle 700 are also operable for DC cable that carries current in both directions, where current flows in one direction along a first side of the cable, and in the opposite direction along a second side of the cable. Such cable embodiments may align along one side or the other of the cradle 700 between parallel portions of the same wiring 703, 704. In various embodiments, the cable may carry AC. The cradle 700 may include a low-impedance inductor that determines the phase of the resonance of the AC, which may allow the controller to switch the direction of the currents in the wiring 703, 704 in phase with the AC of the cable.

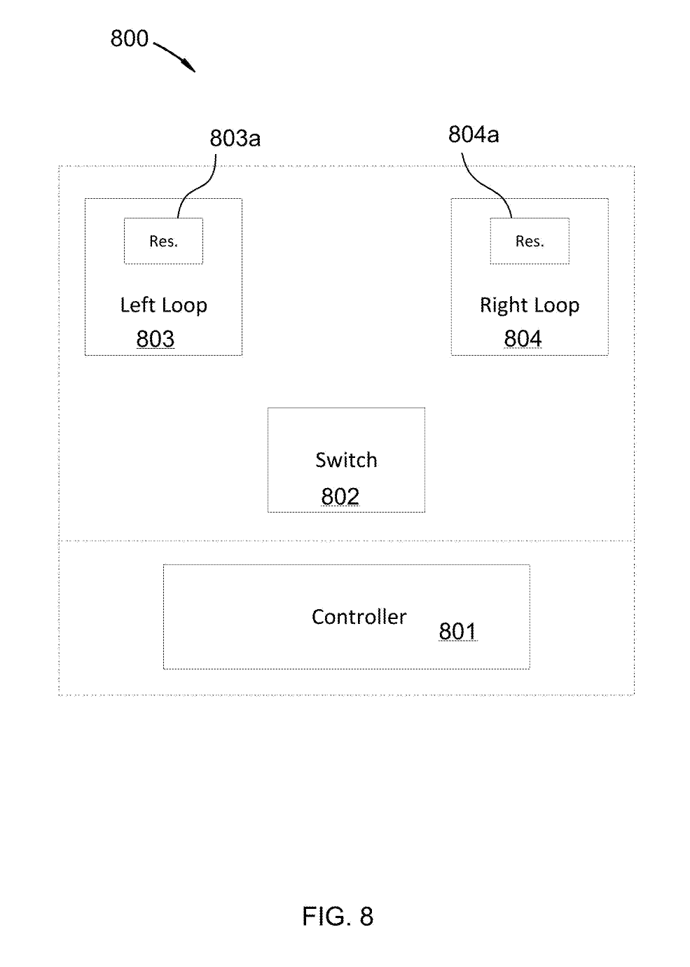

FIG. 8 depicts a more generalized system diagram of the active cradle. The active system 800 includes a controller 801, a switch 802, a left-side loop 803 with a resistive element 803a, and a right-side loop 804 with a resistive element 804a.

Each loop 803, 804, may include one or more resistive elements 803a, 804a, such as light filaments and/or light-emitting diodes (LEDs). The resistive elements 803a, 804a may be any of a variety of other elements, however. In general, the resistive elements 803a, 804a may prevent runaway current in the wiring loops 803, 804. Lighting elements may also serve an additional purpose: notifying a user of a direction to orient the cradle. One or more of the lighting elements may light an arrow formed in the cradle base, as described with regard to FIG.

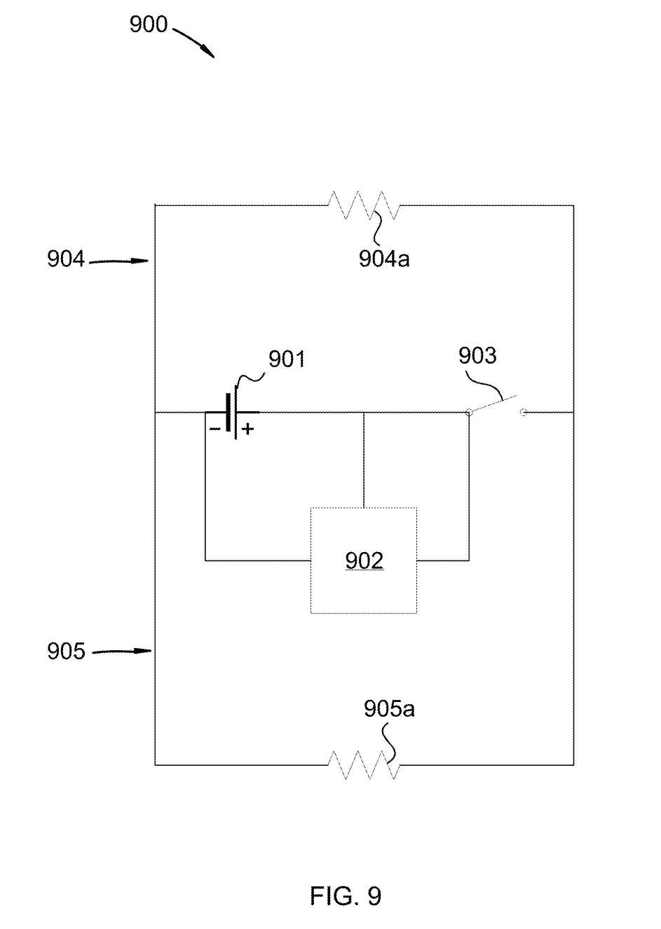

FIG. 9 depicts a partial schematic of an active cradle circuit. The circuit 900 includes a voltage source 901, a controller 902, a switch 903, a first wiring loop 904 having a first resistive element 904a, and a second wiring loop 905 having a second resistive element 905a.

We claim:

1. An active cable management system, comprising:
a channel comprising a base, two walls extending perpendicularly from opposing ends of the base, and one or more sets of opposing openings disposed in the walls;
one or more current-carrying cables running along a length of the channel; and
a cradle disposed in the channel, around the channel walls, or in the channel and around the channel walls, the cradle comprising:
a cradle base, two cradle walls extending perpendicularly from the cradle base, and a set of at least two detents, each detent protruding from at least one of the cradle walls and disposed in at least one of the sets of opposing openings;
first and second wiring disposed in the cradle base, each arranged in a rectangular closed loop, the first wiring passing along first-side edges of the cradle base and across a center portion of the cradle base parallel to the cradle walls, and the second wiring passing along second-side edges of the cradle base and across the center portion of the cradle base parallel to the cradle walls;
a first and a second resistive element connected in series with the first and the second wiring, respectively, and disposed in the cradle base; and
one or more batteries connected to the first and second wiring and a switch connected between the battery and the first and second wiring,
wherein a current passes through the first and second wiring along the center portion of the cradle base in a same direction as a current passing through the cables, attracting the cables towards the center portion of the cradle.

2. The cable management system of claim 1, wherein the cradle is disposed in the channel, the system further comprising a channel cover detachably connected to the channel by a second set of detents, each detent of the second set of detents disposed in at least one of the opposing openings.

3. The cable management system of claim 2, wherein each of the second set of detents is disposed across the corresponding opening from a corresponding one of the first set of detents.

4. The cable management system of claim 1, wherein the channel is disposed above the cradle such that the weight of the cable is against the brace.

5. The cable management system of claim 1, the channel comprising at least two sets of coaxial openings, wherein the brace is disposed between the two sets of coaxial openings.

6. The cable management system of claim 5, wherein the detents are disposed on members extending from the brace towards at least one of the sets of coaxial opposing openings.

7. A cable management system, comprising:
a channel comprising one or more sets of opposing openings;
a cradle disposed in the channel, the cradle comprising a brace and at least two detents, each detent disposed in at least one of the opposing openings; and
one or more cables girdled by the channel, the cradle, or both.

8. The cable management system of claim 7, wherein each set of opposing openings is coaxial, non-coaxial, or combinations thereof.

9. The cable management system of claim 7, wherein the cradle forms a shape complementary to the channel.

10. The cable management system of claim 9, wherein each of the channel and the cradle comprise a base and at least two opposing walls extending from the base.

11. The cable management system of claim 10, wherein the cradle base forms the brace.

12. The cable management system of claim 10, wherein the opposing openings are disposed in the channel walls.

13. The cable management system of claim 12, wherein the detents protrude from outer surfaces of the cradle walls.

14. The cable management system of claim 13, wherein the cradle walls press against inner surfaces of the channel walls, securing the detents in the openings.

15. The cable management system of claim 10, wherein the cradle comprises a first, a second, a third, and a fourth cradle wall, and wherein the channel comprises a first and a second channel wall, wherein the first channel wall is disposed between the first and second cradle walls, and wherein the second channel wall is disposed between the third and fourth cradle walls.

16. The cable management system of claim 15, the detents protruding from an inner surface of the first cradle wall, from an outer surface of the second cradle wall, from an outer surface of the third cradle wall, from an inner surface of the fourth cradle wall, or combinations thereof.

17. The cable management system of claim 15, wherein the detents protruding from the first and second cradle walls are disposed in the same opening or different openings.

18. The cable management system of claim 15, wherein the detents protruding from the third and fourth cradle walls are disposed in the same opening or different openings.

19. The cable management system of claim 7, further comprising one or more horseshoe clips extending from the brace inwards from the cradle.

20. The cable management system of claim 1, wherein the channel base comprises external cleats with barbs for hands-free attachment to the mounting surface.
